(19) United States
(12) Patent Application Publication
(10) Pub. No.: US 2026/0353718 A1
(43) Pub. Date: Nov. 5, 2026

(54) SYSTEMS AND METHODS TO CONTROL CAPACITANCE IN TRENCH MOSFETS

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/664,651

(22) Filed: Apr. 30, 2026

Related U.S. Application Data
(60) Provisional application No. 63/800,226, filed on May 5, 2025.

(51) Int. Cl. H10D 62/10; H10D 30/01; H10D 30/66; H10D 64/27

(52) U.S. Cl. CPC H10D 62/102; H10D 30/0297; H10D 30/668; H10D 64/516; H10D 62/124

(57) ABSTRACT

A trench metal-oxide field-effect transistor (MOSFET) comprises a volume of semiconductor material, a drain, a trench, a source, a gate, and a gate oxide. The volume presents first and second sides and first and second ends. The trench is positioned in the volume. The trench has a trench bottom and opposite first and second laterally spaced trench sides. The source is located adjacent the first trench side. The gate is disposed within the trench and includes a first side surface, a spaced apart second side surface, and a bottom surface positioned at a lower edge therebetween. The gate oxide is positioned between the gate and the trench and includes a first section formed from a first material having a first dielectric constant and a second section formed from a second material having a second dielectric constant, with the first dielectric constant being less than the second dielectric constant.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/800,226; titled “SYSTEMS AND METHODS TO CONTROL CAPACITANCE IN TRENCH MOSFETS;” and filed May 5, 2025. The Provisional Application is hereby incorporated by reference, in its entirety, into the current patent application.

### FIELD

Various examples of the current technology relate to trench-type metal oxide semiconductor field effect transistors (MOSFETs) that have a reduced gate to drain capacitance and methods of fabricating MOSFETs that have a reduced gate to drain capacitance.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

The background discussion is intended to provide information related to the present technology which is not necessarily prior art.

### SUMMARY

Various examples of the current technology address one or more of the above-mentioned issues (or other issues) and provide trench-type metal oxide semiconductor field effect transistors (MOSFETs) that include a gate oxide formed in part from a lower dielectric constant material, resulting in a reduced gate to drain capacitance which allows the MOSFETs to switch on and off at a higher frequency.

An example of the trench MOSFET comprises a volume of semiconductor material, a drain, a trench, a first source, a gate, and a gate oxide. The volume of semiconductor material presents laterally spaced first and second sides and vertically spaced first and second ends. The trench is positioned in the volume of semiconductor material and extends from the first end into the volume of semiconductor material. The trench has a trench bottom and opposite first and second laterally spaced trench sides. The first and second trench sides extend between the trench bottom and the first end. The first source is located adjacent the first trench side. The gate is disposed within the trench and includes a first side surface, a spaced apart second side surface, and a bottom surface. The bottom surface is spaced from the first end of the volume of semiconductor material and extends between the side surfaces. The gate oxide is positioned between the gate and the trench and includes a first portion formed from a first material having a first dielectric constant and a second portion formed from a second material having a second dielectric constant. The first dielectric constant is less than the second dielectric constant.

Another example concerns a method of forming a trench MOSFET. The method includes the following operations. A volume of semiconductor material may be provided to present laterally spaced first and second sides and vertically spaced first and second ends. A trench may be formed in the volume of semiconductor material to extend from the first end. The trench may be formed to have a trench bottom and opposite first and second laterally spaced trench sides, with the first and second trench sides extending between the trench bottom and the first end. A first source may be formed adjacent the first trench side. A drain may be formed. A gate may be formed within the trench to include a first side surface, a laterally spaced apart second side surface, and a bottom surface spaced from the first end of the volume of semiconductor material and positioned between the side surfaces. A gate oxide may be formed between the gate and the trench. The gate oxide may be formed to include a first oxide portion having a first dielectric constant and a second oxide portion having a second dielectric constant that is greater than the first second dielectric constant.

The preceding examples may include any one or more of the following features.

The drain may be positioned at the second end of the volume of semiconductor material.

The first portion of the gate oxide may be positioned between the bottom surface of the gate and the trench bottom, and the second portion of the gate oxide may be positioned between the first side surface of the gate and the first trench side.

The first portion of the gate oxide may have a first thickness defined along a first axis extending between the first and second ends, and the second portion of the gate oxide may have a second thickness defined along a second axis extending between the first and second sides of the volume of semiconductor material, with the first thickness being greater than the second thickness.

The first thickness may be approximately fifty percent (50%) greater than the second thickness.

The first dielectric constant may have a value of approximately four (4).

The first portion of the gate oxide may be positioned between the second side surface of the gate and the second trench side.

A well may be provided. The well may have an opposite dopant polarity than the first source, and the well may extend continuously along the second trench side and partly under the trench bottom.

The first portion of the gate oxide may have a first thickness defined along a first axis extending between the first and second ends. The first portion may also have a second thickness defined along a second axis extending between the first and second sides of the volume of semiconductor material. The second portion of the gate oxide may have a third thickness defined along the second axis, with the first thickness and the second thickness being greater than the third thickness.

The second portion of the gate oxide may be positioned between the second side surface of the gate and the second trench side.

The trench MOSFET may include a second source located adjacent the second trench side.

The trench MOSFET may include a first channel extending between the first source and the drain, wherein electric current flows along the first channel. The trench MOSFET may further include a second channel extending between the second source and the drain, wherein electric current flows along the second channel.

The trench may abut N+ material and P well material on the first trench side and the second trench side.

The first dielectric constant may have a value of approximately four (4).

The first portion of the gate oxide may extend along at least one of the trench sides and the trench bottom. The second portion of the gate oxide may extend along at least one other of the trench sides and the trench bottom. The first portion of the gate oxide may have a first thickness defined transverse to the direction of extension thereof, and the second portion of the gate oxide may have a second thickness defined transverse to the direction of extension thereof. The first thickness may be greater than the second thickness.

The first thickness may be approximately fifty percent (50%) greater than the second thickness.

The step of providing the first oxide portion may include the step of positioning the first oxide portion between the bottom surface of the gate and the trench bottom, and the step of providing the second oxide portion including positioning the second oxide portion between the first side surface of the gate and the first trench side.

The step of providing the first oxide portion may include the step of growing the first oxide portion to have a first thickness defined along a first axis extending between the first and second ends, and the step of providing the second oxide portion may include the step of growing the second oxide portion to have a second thickness defined along a second axis extending between the first and second sides of the volume of semiconductor material. The first thickness may be greater than the second thickness.

The step of providing the first oxide portion may include the step of positioning the first oxide portion between the second side surface of the gate and the second trench side; and forming a well, which has an opposite dopant polarity than the first source, continuously along the second trench side and partly under the trench bottom.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic cross-sectional view of a trench-type metal oxide semiconductor field effect transistor (MOSFET), constructed in accordance with various examples of the current technology and including a gate oxide formed in part from a lower dielectric constant material to lower capacitance and provide reduced switching times;

FIG. 2 is a schematic cross-sectional view of a second example of the trench-type MOSFET;

FIGS. 3A, 3B, 3C, 3D, 3E, and 3F illustrate portions of the field effect transistor during a plurality of operations of a method for fabricating the first example of the trench-type MOSFET;

FIG. 4 includes a plurality of blocks listing at least a portion of the operations of the method for fabricating the first example of the trench-type MOSFET;

FIGS. 5A, 5B, 5C, 5D, 5E, 5F, and 5G illustrate portions of the field effect transistor during a plurality of operations of a method for fabricating the second example of the trench-type MOSFET; and

FIG. 6 includes a plurality of blocks listing at least a portion of the operations of the method for fabricating the second example of the trench-type MOSFET.

The drawing figures do not limit the current technology to the specific examples disclosed and described herein. The drawings are not necessarily to scale, emphasis instead being placed upon clearly illustrating the principles of the technology.

### DETAILED DESCRIPTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In the following description, the word “voltage” may be used to describe electric voltage, the word “current” may be used to describe electric current, and the word “power” may be used to describe electric power. Relational and/or directional terms, such as “above,” “below,” “up,” “upper,” “upward,” “down,” “lower,” “downward,” “top,” “bottom,” “outer,” “inner,” “left,” “right,” etc., along with orientation terms, such as “horizontal” (or “lateral”)_ and “vertical,” may be used throughout this description. These terms retain their commonly accepted definitions and are used with reference to examples of the technology and the positions, directions, and orientations thereof shown in the accompanying figures. However, examples of the technology in practice may be positioned and oriented in other ways or move in other directions. Therefore, the terms do not limit the scope of the current technology.

Metal oxide semiconductor field effect transistors (MOSFETs) generally comprise a semiconductor body that includes a gate, a source, and a drain. Silicon (Si) is typically used as the semiconductor material, although in high voltage applications, silicon carbide (SiC) is utilized. The drain is positioned at one end of the body, and the source is positioned apart from the source (often at an opposite end of the body), with a drift region positioned therebetween. The gate is typically positioned in proximity to the source. In a trench-type MOSFET, the gate extends alongside the source and is positioned within a trench, or cavity, in the body. Furthermore, a gate oxide, formed from or including dielectric or electrically insulating material, is positioned between the gate and the body. Given the structure of the gate, the gate oxide, and the drain, a capacitor between the gate and the drain, Cgd, exists.

During operation of the MOSFET, applying voltage to the gate at a first voltage level allows for increased current flow in the drift region, which switches the MOSFET on. Applying voltage to the gate at a second voltage level results in decreased current flow in the drift region, which switches the MOSFET off. A period of time to switch the MOSFET on (which may be considered charging the gate-drain capacitor Cgd) and a corresponding period of time to switch the MOSFET off (which may be considered discharging the gate-drain capacitor Cgd) vary according to a value of a capacitance of the structural combination. In a simplified form, an equation to determine the switch on time and the corresponding switch off time of the MOSFET is given as: t = C×R, wherein t is the time (in seconds), C is the capacitance of the structural combination, and R is a resistance of circuitry used to apply voltage to the gate. Thus, the switching time of the MOSFET may be reduced by reducing the capacitance of the gate-drain capacitor Cgd.

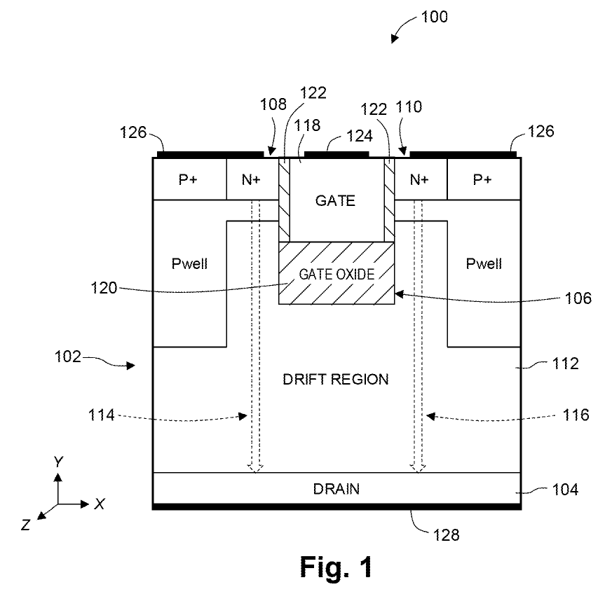

Referring to FIG. 1, a first example of an improved trench MOSFET 100 is shown. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. The trench MOSFET 100 broadly comprises a volume of semiconductor material 102, a drain 104, a trench 106, a first source 108, a second source 110, a drift region 112, a first channel 114, a second channel 116, a gate 118, and a gate oxide. In addition, the MOSFET 100 includes a plurality of electrodes or contacts.

The body or volume of semiconductor material 102 presents a first (or top) end, a second (or bottom) end opposite and vertically spaced (along a Y direction when viewing FIG. 1) from the first end, a first (or left) side, and a second (or right) side opposite and laterally spaced (along an X direction) from the first side. In addition, the volume of semiconductor material 102 may have a front end and a back end opposite and axially spaced (along a Z direction) from the front end. The volume of semiconductor material 102 may be formed from or include an N- epitaxial (epi) semiconductor material.

It will also be appreciated that the sides of the illustrated volume of semiconductor material 102 are defined herein merely to represent a single transistor cell comprising the illustrated MOSFET 100. In practice, the volume of semiconductor material 102 may extend laterally beyond the bounds illustrated in the drawings (leftward and rightward along the X direction and/or fore and aft along the Z direction) to present additional semiconductor material in which additional devices may be provided. Such additional devices may be other MOSFETs 100 or may be entirely different devices providing different operations or functions than the MOSFET 100.

The drain 104 is positioned at the second (bottom) end of the volume of semiconductor material 102, although in some aspects the drain 104 may be located elsewhere on the volume of semiconductor material 102 (such as the same (or first) end as the first and second sources 108, 110). In the illustrated example, the drain 104 has a layer that is formed from or includes N+ material.

The trench 106 extends into the drift region 112 of the volume of semiconductor material 102 and has spaced-apart first (left) and second (right) trench side surfaces, with a bottom surface positioned therebetween at an orthogonal angle to the side surfaces. The trench side surfaces extend between the trench bottom and the first end of the volume of semiconductor material 102. The depth (along the Y direction) of the trench 106 may be less than or equal to half a height of the volume of semiconductor material 102, although other aspects of the example MOSFET 100 contemplate an alternative depth of the trench 106 that is tuned according to the particular application.

The first source 108 is positioned on the left side of the volume of semiconductor material 102 and may be formed from or include a heavily doped material of a first polarity type, i.e., N or P. In an example shown in the figures, the first source 108 is formed from or includes N+ material. An adjacent first well formed from or including material of a second, opposite polarity type, i.e., P or N, is located between the first source section and the drift region 112. In an example shown in the figures, the first well is formed from or includes P material. A first doped region (or body contact) is positioned alongside the first source 108 and the adjacent first well. The first doped region is formed from or includes doped or heavily doped material of the second polarity type, e.g., P+ material. The first source 108 is further positioned adjacent to the first trench side surface.

The second source 110 is positioned on the right side of the volume of semiconductor material 102 and has a structure that may mirror the structure of the first source 108. Accordingly, the second source 110 may be formed from or include a heavily doped material of the first polarity type, e.g., N+. An adjacent second well (which may be formed from or include material of the second polarity type, e.g., P material) is located between the second source section and the drift region 112. A second doped region or body contact (which may be formed from or include doped or heavily doped material of the second polarity type, e.g., P+ material) is positioned alongside the second source 110 and the adjacent second well. The second source 110 is further positioned adjacent to the second trench side surface. In the illustrated example, the first and second sources 108, 110 may be shorted and thereby constitute a common source with left and right source sections. Further, according to certain alternative examples, the transistor sides may be dissimilarly configured. For example, certain aspects contemplate the first source and second source being differently shaped and/or sized (rather than being mirrored structures). The first and second wells and the first and second body contacts may also have respective dissimilar shapes and/or dimensions.

The drift region 112 is positioned beneath the trench 106 and the first well of the first source 108 and the second well of the second source 110. The drift region 112 extends to the sides of the volume of semiconductor material 102 as well as an upper edge of the drain 104. The drift region 112 may be formed from or include N-doped epitaxial (epi) material.

The first channel 114 and the second channel 116 each provide a path for majority charge carrier movement and electric current flow between the sources 108, 110 and the drain 104. The first channel 114 is positioned to the left side of the volume of semiconductor material 102 and extends between the first source 108 and the drain 104. The second channel 116 is positioned to the right side of the volume of semiconductor material 102 and extends between the second source 110 and the drain 104.

The gate 118 generally has a voltage applied to it that turns the MOSFET 100 on and off according to a level of the voltage. That is, at a first voltage level, the MOSFET 100 is turned on, and at a second voltage level, the MOSFET 100 is turned off. The gate 118 has a generally rectangular cuboid shape with a top surface, left and right side surfaces, and a bottom surface. The gate 118 is positioned at the first, or top, end of the structure of the volume of semiconductor material 102 within the trench 106. The gate 118 is formed from or includes polysilicon, a metal or alloy of metals, or other suitable material.

The gate oxide provides electrical insulation (very high resistance) between the gate and the drift region 112 and is, thus, positioned therebetween. In examples of the MOSFET 100, the gate oxide is positioned in the trench 106 and includes a first gate oxide section 120 and a second gate oxide section 122. The first gate oxide section 120 is positioned between a bottom of the gate 118 and an upper portion of the drift region 112, such that the first gate oxide section 120 is in contact with the bottom surface of the gate 118 and the bottom surface of the trench 106. According to certain aspects, the first gate oxide section may be positioned alternatively or additionally along other surfaces of the trench 106. For example, if the drain 104 is alternatively positioned elsewhere than along the second (bottom) end of the volume of semiconductor material 102, it is within the ambit of certain examples for the first gate oxide section to be alternatively located (i.e., other than along the bottom surface of the trench 106). The first gate oxide section 120 has a first thickness (along the Y direction). In addition, the first gate oxide section 120 is formed from or includes material that has a first dielectric constant “k.” The first dielectric constant is considered “low,” and the first gate oxide section 120 may be formed of a “low k material,” such as porous silicon dioxide (SiO2), fluorine-doped silicon oxide (SiOF), carbon-doped silicon oxide (SiCOH), organosilicate glass (OSG), silsesquioxanes (SSQ), and various spin-on organic polymers like polyimide, polynorbornenes, and benzocyclobutene; all of which achieve low dielectric constant values by introducing porosity or specific chemical modifications. The first dielectric constant k may have a value of less than or approximately equal to four (4).

The second gate oxide section 122 includes a left subsection and a right subsection. The left subsection is positioned between the left side surface of the trench 106 and the left side surface of the gate 118. The right subsection is positioned between the right side surface of the trench 106 and the right side surface of the gate 118. The left subsection and the right subsection of the second gate oxide section 122 each have a second thickness (along the X direction). The first thickness (of the first gate oxide section 120) may be greater than the second thicknesses (of each of the left and right subsections of the second gate oxide section 122) by at least five percent (5%), at least twenty percent (20%), at least thirty-five percent (35%), or at least fifty percent (50%), without limitation. In the illustrated example, the first thickness is more than fifty percent (50%) greater than the second thickness. Additionally, the left subsection and the right subsection of the second gate oxide section 122 are each formed from or include material, such as silicon dioxide, that has a second dielectric constant k which is greater than the dielectric constant of the first gate oxide section 120 (i.e., greater than a dielectric constant of four (4)).

The electrodes provide electrical contact between various components of the MOSFET 100 and bond wires that connect to a package for the MOSFET 100. Specifically, the MOSFET 100 includes a gate electrode 124 to provide electrical contact with the gate 118, a source electrode 126 to provide electrical contact with the first and second sources 108, 110, and a drain electrode 128 to provide electrical contact with the drain 104. Each electrode 124, 126, 128 is formed from or includes metals or metal alloys.

The capacitance of the gate-drain capacitor Cgd may be given by the following equation: Cgd = (k×ε0×A)/t, wherein k (or “κ” (kappa)) is the dielectric constant, “ε0” is the permittivity of free space, “A” the area (length × width) of the overlap of the bottom surface of the gate 118 with the upper edge of the drift region 112, and “t” is a thickness of the first gate oxide section 120. The dielectric constant k is a property of the first gate oxide section 120. Having a lower dielectric constant material in the first gate oxide section 120 reduces the capacitance of the gate-drain capacitor Cgd, which in turn, allows the MOSFET 100 to switch on and off at a higher frequency.

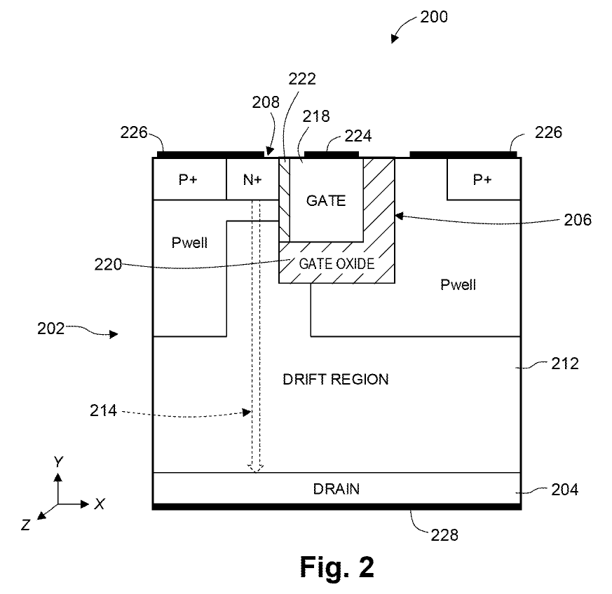

Referring to FIG. 2, a second example of an improved trench MOSFET 200 is shown. The MOSFET 200 is similar to the MOSFET 100, except that the MOSFET 200 includes a single source 208 and a single channel 214. There are also differences between the gate oxide of the MOSFET 100 and a gate oxide of the MOSFET 200. The MOSFET 200 broadly comprises a volume of semiconductor material 202, a drain 204, a trench 206, a drift region 212, a gate 218, a gate electrode 224, a source electrode 226, and a drain electrode 228, each of which is substantially similar to, or the same as, in structure and function compared to the like-named components for the MOSFET 100.

The source 208 is substantially similar to, or the same as, the first source 108 and is positioned on the left side of the volume of semiconductor material 202. The source 208 includes an N+ region in contact with the left side surface of the trench 206 and an adjacent first well (which may be formed from or include P material) located between the source 208 section and the drift region 212 and also in contact with the left side surface of the trench 206. A second well (which may be formed from or include P material) is positioned on the right side of the volume of semiconductor material 202 and is in contact with the right side surface and the bottom surface of the trench 206.

The channel 214 is substantially similar to, or the same as, the first channel 114 and extends between the source 208 and the drain 204. However, it is again noted that the MOSFET 200 is a single channel device, while the MOSFET 100 is a dual channel device.

The gate oxide of the MOSFET 200 is similar to the gate oxide of the MOSFET 100 in that it includes a first gate oxide section 220 and a second gate oxide section 222. The first gate oxide section 220 may include a bottom subsection and a right side subsection. The bottom subsection is positioned between a bottom of the gate 218 and an upper portion of the drift region 212, such that the bottom subsection is in contact with the bottom surface of the gate 218 and the bottom surface of the trench 206. The right side subsection extends between the right side of the gate 218 and the P well on the right side of the volume of semiconductor material 202, such that the right side subsection is in contact with the right side surface of the gate and the right side surface of the trench 206. The bottom subsection has a first thickness (along the Y direction) that is roughly equivalent to a second thickness of the right side subsection (along the X direction). Like the first gate oxide section 120, the first gate oxide section 220 is formed from or includes material that has a low dielectric constant k, with a value of less than or approximately equal to four (4).

The second gate oxide section 222 is positioned between the left side surface of the trench 206 and the left side surface of the gate 218. The second gate oxide section 222 has a third thickness (along the X direction). The first thickness (of the bottom subsection of the first gate oxide section 220) and the second thickness (of the right side subsection of the first gate oxide section 220) are each greater than the third thickness by at least five percent (5%), at least twenty percent (20%), at least thirty-five percent (35%), or at least fifty percent (50%), without limitation. In the illustrated example, the first and second thicknesses are more than fifty percent (50%) greater than the third thickness. In addition, the second gate oxide section 222 is formed from or includes material that has a dielectric constant “k” that is greater than four (4).

Furthermore, as with the MOSFET 100, having a lower dielectric constant material in the first gate oxide section 220 of the MOSFET 200 reduces the capacitance of the gate-drain capacitor Cgd, which in turn, allows the MOSFET 200 to switch on and off at a higher frequency.

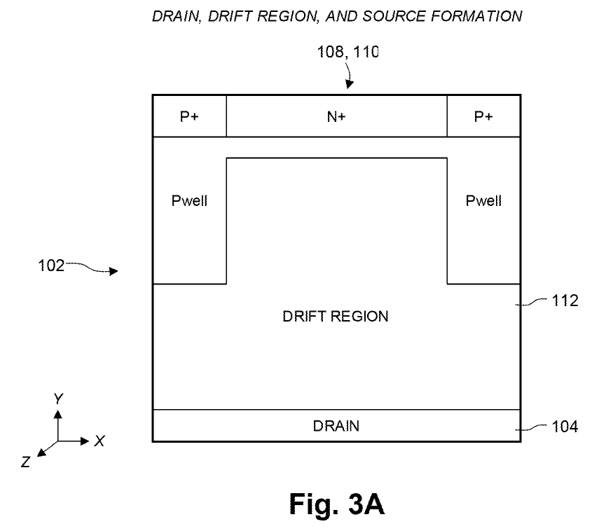

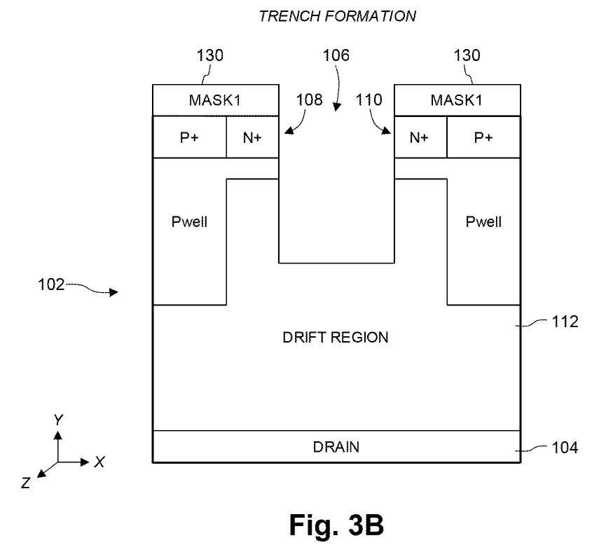

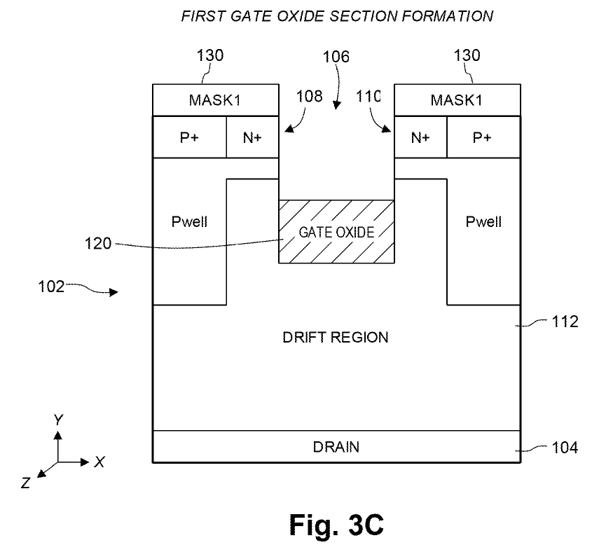

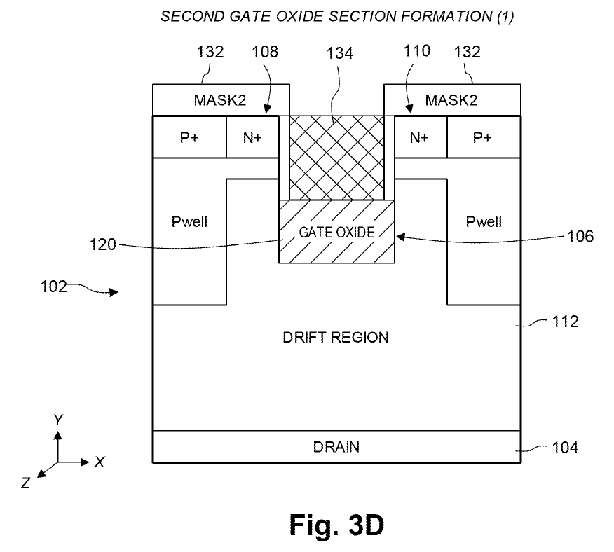

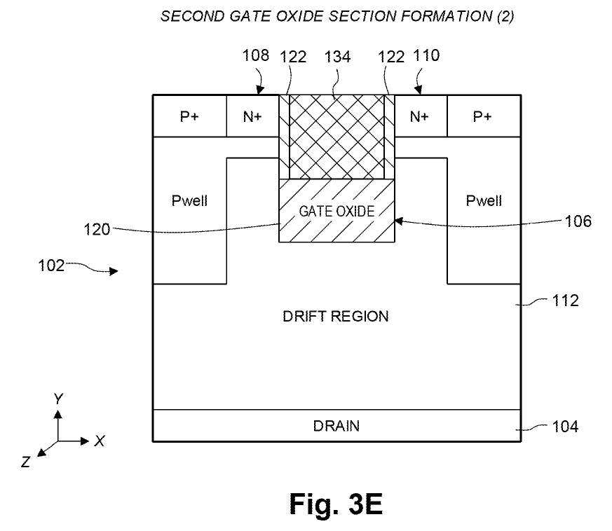

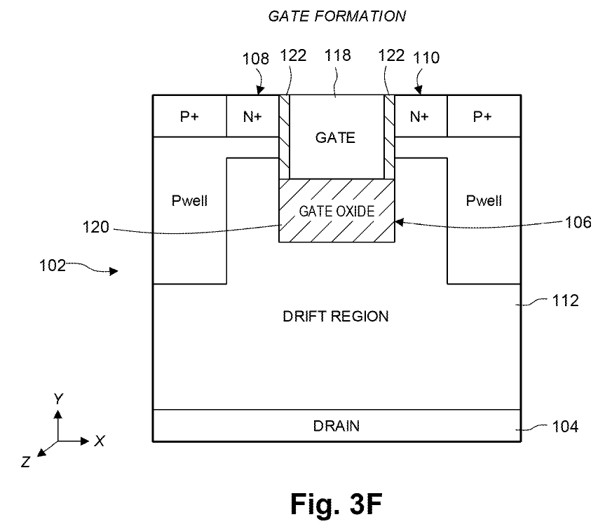

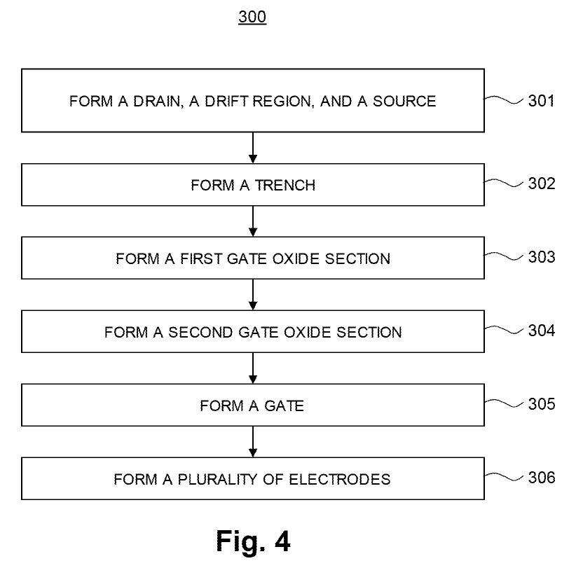

Referring to FIGS. 3A-3E, portions of the MOSFET 100 are shown during various operations of a method 300 for fabricating the MOSFET 100, such that the MOSFET 100 includes a portion of the gate oxide has a reduced dielectric constant. In addition, each operation of the method 300 may be listed in a respective one of a plurality of blocks shown in FIG. 4. Each operation discussed may include numerous sub operations.

Referring to block 301 and FIG. 3A, a drain 104, a drift region 112, a first source 108, and a second source 110 are formed. The drain (or substrate) 104 and the volume of semiconductor material 102 may be formed in a stack utilizing various techniques for epitaxial crystal growth, although certain aspects contemplate alternative means for providing the drain and volume of semiconductor material. For example, a substrate forming the drain may be provided and the volume of semiconductor material 102 may then be epitaxially grown on the substrate. The semiconductor material may be grown to a height of a top of the drift region 112. Again, the drain 104 may be formed by providing an N+ substrate below the second (bottom) end of the volume of semiconductor material. The volume of semiconductor material 102 (including the drift region 112) may be epitaxially grown with the N- doping concentration, although alternative examples contemplate implanting the semiconductor material with N- material.

A well, specifically a P well, is formed by implanting P material into the volume of semiconductor material 102 at a first depth (along the Y direction) on the left and right sides of the semiconductor material 102 and at a second depth in the center portion of the material 102, wherein the first depth is greater than the second depth.

The first source 108 and the second source 110 are formed as a monolithic unit initially by implanting N + material in the upper center portion of the volume of semiconductor material 102. P + regions are formed on opposite sides of the first and second source 108, 110 unit by implanting P + material into the left and right sides of the volume of semiconductor material 102. Various masking techniques may be used to facilitate implantation of the transistor components.

Referring to block 302 and FIG. 3B, a trench 106 is formed by placing a first mask 130 over the upper surface of the volume of semiconductor material 102. The first mask 130 includes at least one opening positioned in alignment with the center portion of the drift region 112, wherein the opening extends laterally (along the X direction) and axially (along the Z direction). With the first mask 130 in place, an etch, such as a dry etch, is applied to the volume of semiconductor material 102 through the opening in the first mask 130. The etch removes a portion of the first and second source 108, 110 unit (thereby forming the separate first source 108 and second source 110) as well as a portion of the P well and a portion of the drift region 112. The trench 106 that is formed includes a left side surface, a right side surface, and a bottom surface.

Referring to block 303 and FIG. 3C, a first gate oxide section 120 is formed. Oxide having a first dielectric constant k is deposited in the trench 106 along the bottom surface and along a portion of each of the right side surface and the left side surface so that the first gate oxide section 120 occupies only a lower portion of the trench 106.

Referring to block 304, a second gate oxide section 122 is formed. As shown in FIG. 3D, a second mask 132 is placed over the upper surface of the volume of semiconductor material 102. The second mask 132 includes at least one opening positioned in alignment with the trench 106, wherein the opening has a lateral width (along the X direction) which is smaller than a width of the trench 106, such that the left and right edges of the opening are inset from the left and right side surfaces, respectively, of the trench 106. Material(s) including nitride is deposited through the opening into the trench 106 to form a filler block 134.

As shown in FIG. 3E, oxide having a second dielectric constant k is deposited in a left gap between the left side surface of the trench 106 and the filler block 134 and a right gap between the right side surface of the trench 106 and the filler block 134. After the deposition, the filler block 134 is removed (by etching), so that the second gate oxide section 122 remains.

Referring to block 305 and FIG. 3F, a gate 118 is formed. The gate 118 is formed by depositing material that includes polysilicon, a metal or alloy of metals, or other suitable material into the trench 106 to contact the first gate oxide section 120 and the second gate oxide section 122.

Referring to block 306 and FIG. 1, a plurality of electrodes are formed. The electrodes include a gate electrode 124 to provide electrical contact with the gate 118, a source electrode 126 to provide electrical contact with the first and second sources 108, 110, and a drain electrode 128 to provide electrical contact with the drain 104. Each electrode 124, 126, 128 is formed by depositing metal or a metal alloy on the gate 118, the first and second sources 108, 110, and drain 104, respectively.

Additional processing may be performed if desired.

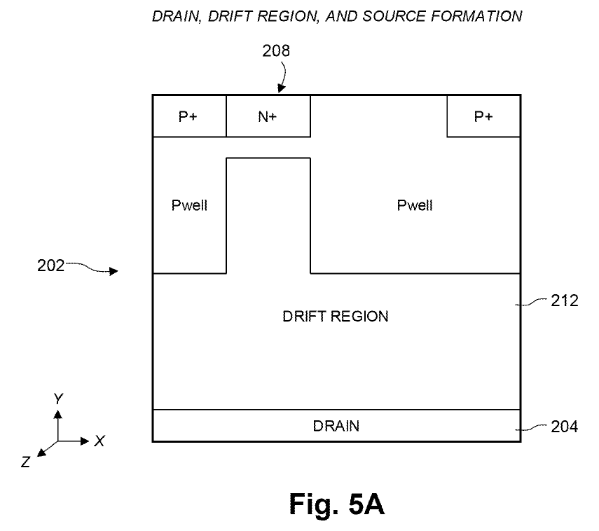

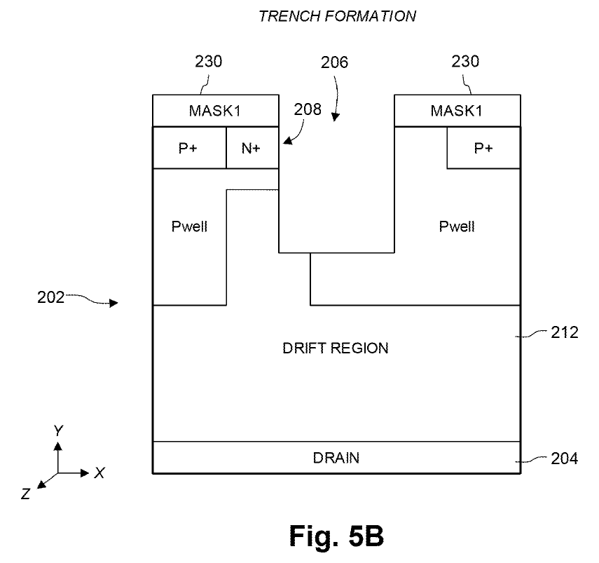

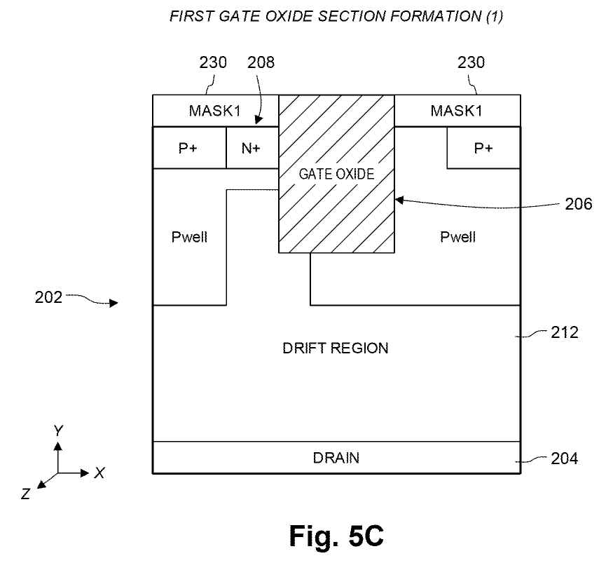

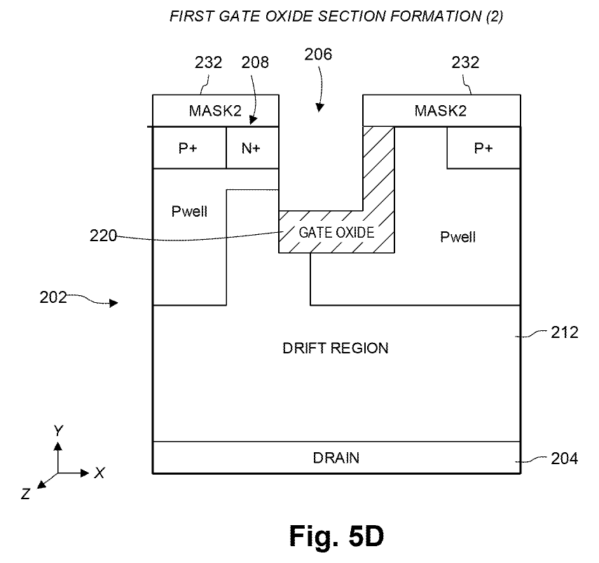

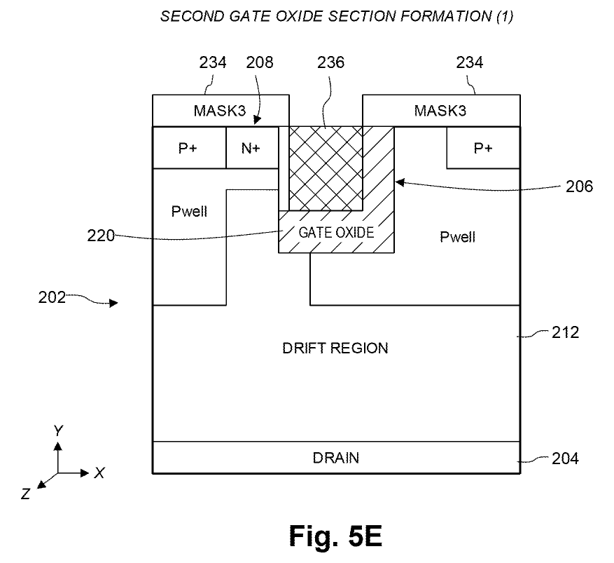

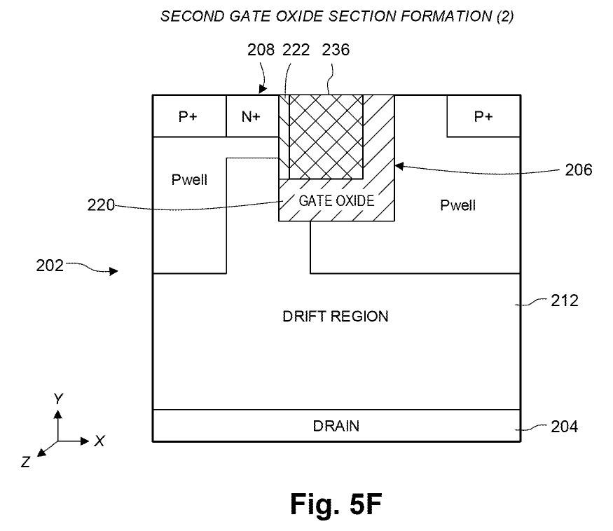

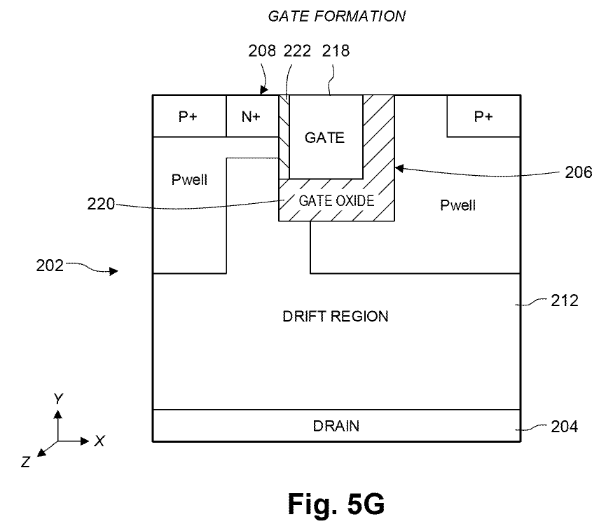

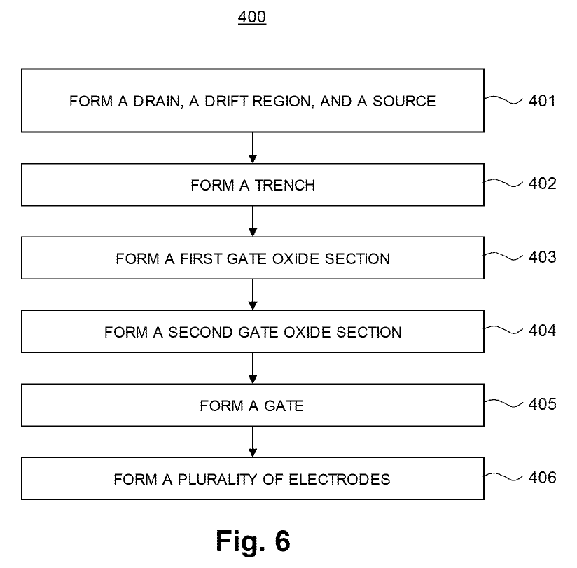

Referring to FIGS. 5A-5G, portions of the MOSFET 200 are shown during various operations of a method 400 for fabricating the MOSFET 200, such that the MOSFET 200 includes a gate oxide having a reduced dielectric constant. In addition, each operation of the method 400 may be listed in a respective one of a plurality of blocks shown in FIG. 6. Each operation discussed may include numerous sub operations.

Referring to block 401 and FIG. 5A, a drain 204, a drift region 212, and a source 208 are formed. The drain (or substrate) 204 and the volume of semiconductor material 202 may be formed in a stack utilizing various deposition techniques for epitaxial crystal growth, although certain aspects contemplate alternative means for providing the drain and volume of semiconductor material. For example, a substrate forming the drain may be provided and the volume of semiconductor material 202 may then be epitaxially grown on the substrate. The semiconductor material may be grown to a height of a top of the drift region 212. Again, the drain 204 may be formed by providing an N+ substrate below the second (bottom) end of the volume of semiconductor material. The volume of semiconductor material 202 (including the drift region 212) may be epitaxially grown with the N- doping concentration, although alternative examples contemplate implanting the semiconductor material with N- material.

A well, specifically a P well, is formed by implanting P material into the volume of semiconductor material 202 at a first depth (along the Y direction) on the left and right sides of the semiconductor material 202 and at a second depth in the center portion of the material 202, wherein the first depth is greater than the second depth. In certain examples, the left side of the P well may have a smaller lateral width (along the X direction) than the right side of the P well.

The source 208 is formed by implanting N + material in the center portion of the volume of semiconductor material 202 (or P well). A P + region is formed on the right side of the P well by implanting P + material into the right side of the P well.

Referring to block 402 and FIG. 5B, a trench 206 is formed by placing a first mask 230 over the upper surface of the volume of semiconductor material 202. The first mask 230 includes at least one opening positioned in alignment with the center portion of the volume of semiconductor material 202, wherein the opening extends laterally (along the X direction) and axially (along the Z direction). With the first mask 230 in place, an etch, such as a dry etch, is applied to the volume of semiconductor material 202 through the opening in the first mask 230. The etch removes a portion of the P well and a portion of the drift region 212. The trench 206 that is formed includes a left side surface, a right side surface, and a bottom surface.

Referring to block 403, a first gate oxide section 220 is formed. As shown in FIG. 5C, the first mask 230 is left in place and oxide having a first dielectric constant k is deposited in the trench 206 so as to occupy most or all of the trench 206. As shown in FIG. 5D, the first mask 230 is removed and a second mask 232 is placed over the upper surface of the volume of semiconductor material 202. The second mask 232 includes at least one opening positioned in alignment with the center portion of the drift region 212, wherein the opening extends laterally (along the X direction) and axially (along the Z direction). In addition, the opening overlaps at least a portion of the trench 206 on the right side and the oxide therein. An etch, such as a dry etch, is applied to the oxide through the opening in the second mask 232, which removes a portion of the oxide to form the first gate oxide section 220.

Referring to block 404, a second gate oxide section 222 is formed. As shown in FIG. 5E, a third mask 234 is placed over the upper surface of the volume of semiconductor material 202. The third mask 234 includes at least one opening that is sized and positioned similarly to the opening of the second mask 232 – except that the left edge of the opening is inset from the left side surface of the trench 206. Material(s) including nitride is deposited through the opening into the trench 206 to form a filler block 236.

As shown in FIG. 5F, oxide having a second dielectric constant k (which is greater than the first dielectric constant) may be deposited in a left gap between the left side surface of the trench 206 and the filler block 236. After the deposition, the filler block 236 is removed (by etching), so that the second gate oxide section 222 remains.

Referring to block 405 and FIG. 3G, a gate 218 is formed. The gate 218 is formed by depositing material that includes polysilicon, a metal or alloy of metals, or other suitable material into the trench 206 to contact the first gate oxide section 220 and the second gate oxide section 222.

Referring to block 406 and FIG. 2, a plurality of electrodes are formed. The electrodes include a gate electrode 224 to provide electrical contact with the gate 218, a source electrode 226 to provide electrical contact with the source 208, and a drain electrode 228 to provide electrical contact with the drain 204. Each electrode 224, 226, 228 is formed by depositing metal or a metal alloy on the gate 218, source 208, and drain 204, respectively.

Additional processing may be performed if desired.

### General Considerations

Although described herein with regard or in relation to one or more particular kinds of electronic devices (e.g., a trench-type metal oxide semiconductor field-effect transistor), the technology may be more broadly applicable to one or more other kinds of electronic devices as well.

Additionally, the various example materials identified herein may, in some aspects, be replaced and/or supplemented with substantially any other suitable material. For example, gate material may include polysilicon, a metal or alloy of metals, or other suitable material; gate oxide or dielectric may include silicon dioxide (SiO2), aluminum oxide (Al2O3), hafnium dioxide (HfO2), silicon nitride (Si3N4), or other suitable material; and semiconductor material may include silicon (Si), silicon carbide (SiC), gallium nitride (GaN), zinc oxide (ZnO), or other suitable material.

Additionally, in general, unless otherwise specified or unless one with ordinary skill in the art would understand otherwise, doping characterized as "++" (e.g., P++) will have a relatively higher concentration of dopants than "+" (e.g., P+) doping, "+" doping will have a relatively higher concentration than "-well" (e.g., P-well) doping, and "-well" doping will have a relatively higher concentration of doping than "-" (e.g., P-) doping. In general, doping concentrations (typically measured in parts-per-cubic-centimeter) for contact implants (e.g., sources, drains, body contacts) may be approximately between 5x10^18 and 1x10^22; doping concentrations for channel and threshold forming implants (e.g., P-wells) may be approximately between 5x10^15 and 5x10^17; doping concentrations for shielding implants may be approximately between 5x10^17 and 5x10^19; doping concentrations for conductivity improvement implants (e.g., N- doping in the junction field-effect transistor neck region of a metal oxide semiconductor field-effect transistor) may be approximately between 1x10^17 and 1x10^19; and doping concentrations for drift regions (e.g., N doping) may be approximately between 1x10^15 and 1x10^16. In some examples, the doping concentration range for the drift region may be widened, for example to approximately between 1x10^14 and 1x10^18.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of a volume of semiconductor material may be to the conceptual limit of a particular unit cell and not to an actual physical end of the material.

Throughout this specification, references to “one example,” “an example,” or “examples” mean that the feature or features being referred to are included in at least one example of the technology. Separate references to “one example,” “an example,: or “examples” in this description do not necessarily refer to the same example and are also not mutually exclusive unless so stated or except as will be readily apparent to those skilled in the art from the description. For example, a feature, structure, act, etc. described in one example may also be included in other examples, but is not necessarily included. Thus, the current technology can include a variety of combinations, integrations, or both, of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated or claimed. For instance, although the claims recite formation of the trench as an initial step, the doped regions forming the source, well, body contact, and drain may be implanted, formed, or otherwise provided before the trench is formed (as disclosed in the illustrated examples). Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A trench metal-oxide field-effect transistor (MOSFET) comprising:
a volume of semiconductor material presenting laterally spaced first and second sides and vertically spaced first and second ends;
a trench positioned in the volume of semiconductor material,
the trench extending from the first end into the volume of semiconductor material and having a trench bottom and opposite first and second laterally spaced trench sides, the first and second trench sides extending between the trench bottom and the first end;
a first source located adjacent the first trench side;
a drain;
a gate disposed within the trench,
the gate including a first side surface, a laterally spaced apart second side surface, and a bottom surface that is spaced from the first end of the volume of semiconductor material and extends between the side surfaces; and
a gate oxide positioned between the gate and the trench,
the gate oxide including a first portion formed from a first material having a first dielectric constant and a second portion formed from a second material having a second dielectric constant,
the first dielectric constant being less than the second dielectric constant.

2. The trench MOSFET of claim 1, wherein the drain is positioned at the second end of the volume of semiconductor material.

3. The trench MOSFET of claim 1, wherein the first portion of the gate oxide is positioned between the bottom surface of the gate and the trench bottom, and the second portion of the gate oxide is positioned between the first side surface of the gate and the first trench side.

4. The trench MOSFET of claim 3, wherein the first portion of the gate oxide has a first thickness defined along a first axis extending between the first and second ends, and the second portion of the gate oxide has a second thickness defined along a second axis extending between the first and second sides of the volume of semiconductor material, with the first thickness being greater than the second thickness.

5. The trench MOSFET of claim 4, wherein the first thickness is approximately fifty percent (50%) greater than the second thickness.

6. The trench MOSFET of claim 5, wherein the first dielectric constant has a value of approximately four (4).

7. The trench MOSFET of claim 3, wherein the first portion of the gate oxide is positioned between the second side surface of the gate and the second trench side.

8. The trench MOSFET of claim 7, comprising a well that has an opposite dopant polarity than the first source, the well extending continuously along the second trench side and partly under the trench bottom.

9. The trench MOSFET of claim 7, wherein the first portion of the gate oxide has a first thickness defined along a first axis extending between the first and second ends, and a second thickness defined along a second axis extending between the first and second sides of the volume of semiconductor material, and the second portion of the gate oxide has a third thickness defined along the second axis, with the first thickness and the second thickness being greater than the third thickness.

10. The trench MOSFET of claim 3, wherein the second portion of the gate oxide is positioned between the second side surface of the gate and the second trench side.

11. The trench MOSFET of claim 10, comprising a second source located adjacent the second trench side.

12. The trench MOSFET of claim 11, further comprising
a first channel extending between the first source and the drain, wherein electric current flows along the first channel, and
a second channel extending between the second source and the drain, wherein electric current flows along the second channel.

13. The trench MOSFET of claim 10, wherein the trench abuts N+ material and P well material on the first trench side and the second trench side.

14. The trench MOSFET of claim 1, wherein the first dielectric constant has a value of approximately four (4).

15. The trench MOSFET of claim 1, wherein the first portion of the gate oxide extends along at least one of the trench sides and the trench bottom, the second portion of the gate oxide extends along at least one other of the trench sides and the trench bottom, the first portion of the gate oxide having a first thickness defined transverse to the direction of extension thereof, the second portion of the gate oxide having a second thickness defined transverse to the direction of extension thereof, with the first thickness being greater than the second thickness.

16. The trench MOSFET of claim 15, wherein the first thickness is approximately fifty percent (50%) greater than the second thickness.

17. A method of forming a trench metal-oxide field-effect transistor (MOSFET), the method comprising:
providing a volume of semiconductor material presenting laterally spaced first and second sides and vertically spaced first and second ends;
forming a trench in the volume of semiconductor material to extend from the first end and have a trench bottom and opposite first and second laterally spaced trench sides, the first and second trench sides extending between the trench bottom and the first end;
forming a first source adjacent the first trench side;
forming a drain;
forming a gate within the trench to include a first side surface, a laterally spaced apart second side surface, and a bottom surface spaced from the first end of the volume of semiconductor material and positioned between the side surfaces; and
forming a gate oxide between the gate and the trench,
the step of forming the gate oxide including providing a first oxide portion having a first dielectric constant,
the step of forming the gate oxide further including providing a second oxide portion having a second dielectric constant that is greater than the first second dielectric constant.

18. The method of claim 17, wherein the step of providing the first oxide portion including the step of positioning the first oxide portion between the bottom surface of the gate and the trench bottom, and the step of providing the second oxide portion including positioning the second oxide portion between the first side surface of the gate and the first trench side.

19. The method of claim 18, wherein the step of providing the first oxide portion including the step of growing the first oxide portion to have a first thickness defined along a first axis extending between the first and second ends, and the step of providing the second oxide portion including the step of growing the second oxide portion to have a second thickness defined along a second axis extending between the first and second sides of the volume of semiconductor material, with the first thickness being greater than the second thickness.

20. The method of claim 19, comprising:
the step of providing the first oxide portion including the step of positioning the first oxide portion between the second side surface of the gate and the second trench side; and
forming a well, which has an opposite dopant polarity than the first source, continuously along the second trench side and partly under the trench bottom.
